(19) United States
(12) Patent Application Publication
(10) Pub. No.: US 2011/0227154 A1
(43) Pub. Date: Sep. 22, 2011

(54) SEMICONDUCTOR DEVICE AND METHOD OF MANUFACTURING THE SAME

(75) Inventors: Syotaro ONO, Kanagawa-ken (JP); Wataru Saito, Kanagawa-ken (JP); Munehisa Yabuzaki, Hyogo-ken (JP); Shunji Taniuchi, Kanagawa-ken (JP); Miho Watanabe, Tokyo (JP)

(73) Assignee: Kabushiki Kaisha Toshiba, Tokyo (JP)

(21) Appl. No.: 13/052,032

(22) Filed: Mar. 18, 2011

(30) Foreign Application Priority Data
Mar. 19, 2010 (JP) 2010-064057

(51) Int. Cl. H01L 29/78; H01L 21/336

(52) U.S. Cl. 257/335; 438/306; 257/E21.417; 257/E29.256

(57) ABSTRACT

A semiconductor device comprising: a first semiconductor layer of a first conductivity type; a second semiconductor layer of the first conductivity type formed on the first semiconductor layer; a first buried layer of the first conductivity type selectively formed in the second semiconductor layer and having a first peak impurity concentration at a first depth; a second buried layer of a second conductivity type selectively formed in the second semiconductor layer and having a second peak impurity concentration at a second depth; a base layer of the second conductivity type selectively formed in the second semiconductor layer and overlapping with an upper portion of the second buried layer; a source layer of the first conductivity type selectively formed in the base layer; and a gate electrode formed on the base layer and on the second semiconductor layer above the first buried layer with a gate insulating film being interposed therebetween.

### CROSS-REFERENCE TO RELATED APPLICATION

This application claims the benefit of Japanese Application No. 2010-64057 filed in Japan on Mar. 19, 2010, the contents of which are incorporated herein by this reference.

### FIELD

Embodiments described herein relates generally to a semiconductor device and a method of manufacturing the semiconductor device.

### BACKGROUND

A high withstand voltage and a low on-resistance are desired for power semiconductor devices. Conventionally, as a power semiconductor device, a vertical semiconductor device called as a planar-gate DMOS (Double-Diffused MOSFET) transistor has been known. The planar-gate DMOS transistor includes an N-type semiconductor layer formed on an N⁺-type semiconductor layer, a low-concentration P-type base layer and a high-concentration N-type source layer which are formed doubly in the N-type semiconductor layer, and a buried layer formed in the N-type semiconductor layer.

In this conventional DMOS transistor, a P⁻-type epitaxial layer is formed on the N-type semiconductor layer, P-type base layers are formed at predetermined intervals in the P⁻-type epitaxial layer, N-type buried layers reaching the N-type semiconductor layer are formed between the P-type base layers formed at the predetermined intervals, and an N-type impurity layer is formed in a P-type epitaxial layer above the N-type buried layer.

The N-type buried layer allows a depletion layer to be extended toward the P-type epitaxial layer, thus reducing the capacity between a drain and a source and the capacity between the drain and a gate.

However, in the DMOS transistor of this structure, the N-type buried layer does not affect the on-resistance, that is to say, the withstand voltage and the on-resistance are approximately the same as those of a general planar-gate DMOS transistor having no N-type buried layer.

Accordingly, there is a problem in that a planar-gate DMOS transistor having a lower on-resistance with the withstand voltage maintained cannot be obtained.

### BRIEF DESCRIPTION OF THE DRAWINGS

FIG. 1 shows a semiconductor device according to Embodiment 1 of the present invention; FIG. 1A is a cross-sectional view of the semiconductor device; FIG. 1B shows impurity concentration distribution along the line A-A in FIG. 1A; FIG. 1C shows impurity concentration distribution along the line B-B in FIG. 1A.

FIG. 2 shows a semiconductor device of a first comparative example according to Embodiment 1 of the present invention; FIG. 2A shows a cross-sectional view of the semiconductor device; FIG. 2B shows the impurity concentration distribution along the line B-B in FIG. 1A.

FIG. 3 shows a semiconductor device of a second comparative example according to Embodiment 1 of the present invention; FIG. 3A shows a cross-sectional view of the semiconductor device; FIG. 3B shows the impurity concentration distribution along the line D-D in FIG. 3A.

FIG. 4 is a cross-sectional view for sequentially showing the manufacturing process of the semiconductor device according to Embodiment 1 of the present invention.

FIG. 5 is a cross-sectional view for sequentially showing the manufacturing process of the semiconductor device according to Embodiment 1 of the present invention.

FIG. 6 is a cross-sectional view for sequentially showing the manufacturing process of the semiconductor device according to Embodiment 1 of the present invention.

FIG. 7 is a cross-sectional view for sequentially showing the manufacturing process of the semiconductor device according to Embodiment 1 of the present invention.

FIG. 8 is a cross-sectional view for sequentially showing the manufacturing process of the semiconductor device according to Embodiment 1 of the present invention.

FIG. 9 is a cross-sectional view for sequentially showing the manufacturing process of the semiconductor device according to Embodiment 1 of the present invention.

FIG. 10 is a cross-sectional view for sequentially showing the manufacturing process of the semiconductor device according to Embodiment 1 of the present invention.

FIG. 11 shows a semiconductor device according to Embodiment 2 of the present invention; FIG. 11A is a cross-sectional view of the semiconductor device; FIG. 11B shows impurity concentration distribution along the line E-E in FIG. 11A; FIG. 11C shows impurity concentration distribution along the line F-F in FIG. 11A.

FIG. 12 shows a semiconductor device according to Embodiment 3 of the present invention; FIG. 12A is a cross-sectional view of the semiconductor device; FIG. 12B shows impurity concentration distribution along the line G-G in FIG. 12A; FIG. 12C shows impurity concentration distribution along the line H-H in FIG. 12A.

FIG. 13 shows a semiconductor device according to Embodiment 4 of the present invention; FIG. 13A is a cross-sectional view of the semiconductor device; FIG. 13B shows impurity concentration distribution along the line I-I in FIG. 13A; FIG. 13C shows impurity concentration distribution along the line J-J in FIG. 13A.

FIG. 14 is a cross-sectional view for sequentially showing an essential part of the manufacturing process of the semiconductor device according to Embodiment 4 of the present invention.

FIG. 15 is a cross-sectional view for sequentially showing an essential part of the manufacturing process of the semiconductor device according to Embodiment 4 of the present invention.

FIG. 16 is a cross-sectional view for sequentially showing an essential part of the manufacturing process of the semiconductor device according to Embodiment 4 of the present invention.

FIG. 17 shows a semiconductor device according to Embodiment 5 of the present invention; FIG. 17A is a cross-sectional view of the semiconductor device; FIG. 17B shows impurity concentration distribution along the line K-K in FIG. 17A; FIG. 17C shows impurity concentration distribution along the line L-L in FIG. 17A.

FIG. 18 is a cross-sectional view for sequentially showing an essential part of the manufacturing process of the semiconductor device according to Embodiment 5 of the present invention.

FIG. 19 is a cross-sectional view for sequentially showing an essential part of the manufacturing process of the semiconductor device according to Embodiment 5 of the present invention.

FIG. 20 is a cross-sectional view for sequentially showing an essential part of the manufacturing process of the semiconductor device according to Embodiment 5 of the present invention.

FIG. 21 shows a semiconductor device according to Embodiment 6 of the present invention.

FIG. 22 is a cross-sectional view for sequentially showing an essential part of the manufacturing process of the semiconductor device according to Embodiment 6 of the present invention.

FIG. 23 is a cross-sectional view for sequentially showing an essential part of the manufacturing process of the semiconductor device according to Embodiment 6 of the present invention.

FIG. 24 is a cross-sectional view for sequentially showing an essential part of the manufacturing process of the semiconductor device according to Embodiment 6 of the present invention.

### DETAILED DESCRIPTION

One embodiment discloses a semiconductor device comprising: a first semiconductor layer of a first conductivity type; a second semiconductor layer of the first conductivity type, the second semiconductor layer being formed on the first semiconductor layer and having a lower impurity concentration than the first semiconductor layer; a first buried layer of the first conductivity type, the first buried layer being selectively formed in the second semiconductor layer and having a first peak impurity concentration at a first depth from a surface of the second semiconductor layer, the first peak impurity concentration being higher than an impurity concentration directly under the surface of the second semiconductor layer; a second buried layer of a second conductivity type, the second buried layer being selectively formed in the second semiconductor layer and being adjacent to the first buried layer, the second buried layer having a second peak impurity concentration at a second depth from the surface of the second semiconductor layer, the second depth being approximately equal to the first depth; a base layer of the second conductivity type, the base layer being selectively formed in the second semiconductor layer and overlapping with an upper portion of the second buried layer; a source layer of the first conductivity type, the source layer being selectively formed in the base layer and being separated from a side surface of the base layer on the first buried layer side, the source layer having an undersurface located at a third depth, from the surface of the second semiconductor layer, the third depth being shallower than the first depth; and a gate electrode formed on the base layer and on the second semiconductor layer above the first buried layer with a gate insulating film being interposed therebetween.

Exemplary embodiments of the invention will now be described with reference to the drawings. Similar components in the drawings are marked with like reference numerals, and a detailed description is omitted as appropriate.

### Embodiment 1

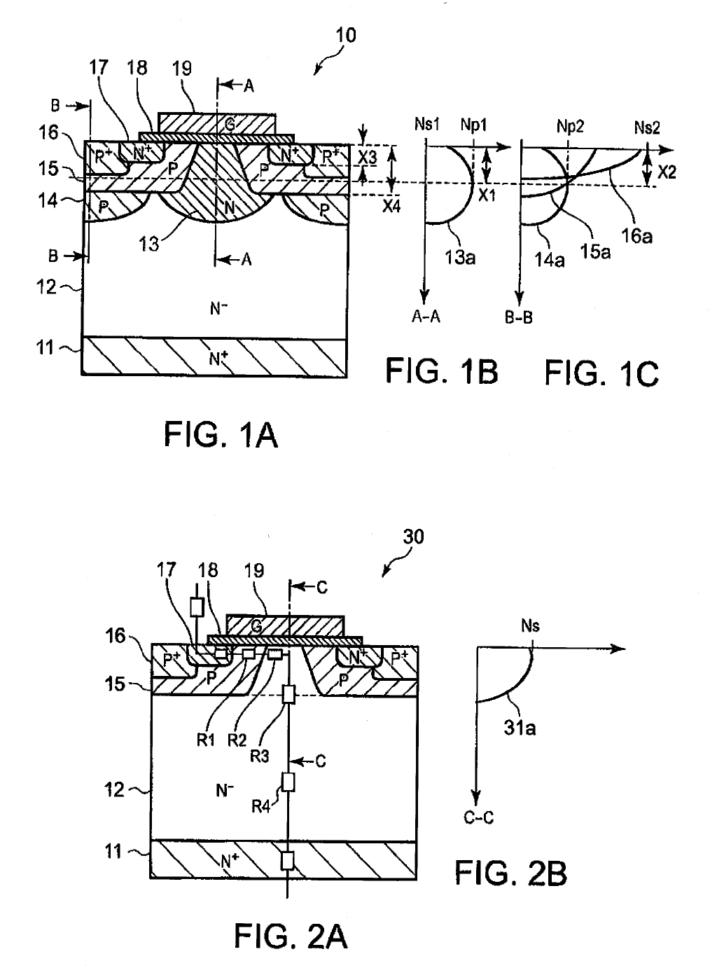

A semiconductor device according to Embodiment 1 of the present invention is described using FIG. 1. FIG. 1 shows the semiconductor device according to Embodiment 1 of the present invention; FIG. 1A is a cross-sectional view of the semiconductor device; FIG. 1B shows impurity concentration distribution along the line A-A in FIG. 1A; FIG. 1C shows impurity concentration distribution along the line B-B in FIG. 1A.

The semiconductor device of the present embodiment is a planar gate DMOS transistor in which a low-concentration P-type base layer and a high-concentration N-type source layer are formed in an N-type semiconductor layer, which is formed on an N⁺-type semiconductor layer. This DMOS transistor has a stripe form in the depth direction, and multiple DMOS transistors are disposed at predetermined intervals in the transverse direction.

As shown in FIG. 1A, in a semiconductor device 10, an N-type second semiconductor layer 12 is formed on an N⁺-type (the first conductivity type) first semiconductor layer 11, the N-type second semiconductor layer 12 having a lower impurity concentration than the first semiconductor layer 11.

The first semiconductor layer 11 is a drain layer. The impurity concentration and thickness of the drain layer are, for example, approximately 1E18 to 1E19 cm⁻³, and 100 μm, respectively. The second semiconductor layer 12 is a drift layer. The impurity concentration and thickness of the drift layer depend on the withstand voltage of given device, and for example, in the case where a withstand voltage of 200 V is to be obtained, the impurity concentration and thickness are approximately 1E15 cm⁻³ and 10 μm.

In the second semiconductor layer 12, an N-type first buried layer 13 is selectively formed in a first depth X1 (hereinafter simply referred to as the depth X1) from the surface of the second semiconductor layer 12, wherein the N-type first buried layer 13 has a first peak impurity concentration Np1 (hereinafter simply referred to as the peak impurity concentration Np1) higher than the impurity concentration Ns1 directly under the surface of the second semiconductor layer 12.

In the second semiconductor layer 12, a P-type (the second conductivity type) second buried layer 14 is selectively formed to the first buried layer 13 in a second depth X2 (hereinafter simply referred to as the depth X2) from the surface of the second semiconductor layer 12, wherein the second buried layer 14 has a second peak impurity concentration Np2 (hereinafter simply referred to as the peak impurity concentration Np2).

The upper surface of the first buried layer 13, and the upper surface of the second buried layer 14 reach the surface of the second semiconductor layer 12, and the first buried layer 13 and the second buried layer 14 adjoin.

As shown in FIG. 1B, an impurity concentration distribution 13a of the first buried layer 13 along the line A-A shows a peak impurity concentration Np1 at the depth X1, and forms a convex curve decreasing in the upward and downward directions of the second semiconductor layer 12. The impurity concentration Ns1 directly under the surface of the second semiconductor layer 12 is smaller than the peak impurity concentration Np1 of the first buried layer 13.

In the second semiconductor layer 12, a P-type base layer 15 is selectively formed on the upper portion of the second buried layer 14, the P-type base layer 15 overlapping with the second buried layer 14. The undersurface of the base layer 15 is located in a fourth depth X4 (hereinafter simply referred to as the depth X4) which is approximately equal to the depth X1 from the surface of the second semiconductor layer 12.

The base layer 15 is formed in such a manner as to overlap also with the upper portion of apart of the first buried layer 13 on the second buried layer 14 side.

In the base layer 15, a P⁺-type third semiconductor layer 16 is selectively formed in the center. The third semiconductor layer 16 is provided to reduce contact resistance between the base layer 15 and a source electrode (not shown).

As shown in FIG. 1C, an impurity concentration distribution 14a of the second buried layer 14 along the line B-B shows the peak impurity concentration Np2 at the depth X1, and forms a convex curve decreasing in the upward and downward directions of the semiconductor layer 12. The peak impurity concentration Np2 is arranged to be approximately equal to the peak impurity concentration Np1.

An impurity concentration distribution 15a of the base layer 15 along the line B-B decreases from the surface of the second semiconductor layer 12 to the inside. Similarly, an impurity concentration distribution 16a of the base layer 16 along the line B-B decreases from the surface of the second semiconductor layer 12 to the inside.

As a result, the total impurity concentration distribution along the line B-B is expressed as the sum of the impurity concentration distribution 14a, the impurity concentration distribution 15a, and the impurity concentration distribution 16a. Accordingly, the impurity concentration Ns2 directly under the surface of the second semiconductor layer 12 is higher than the peak impurity concentration Np2.

In the base layer 15, an N⁺-type source layer 17 is selectively formed such that the source layer 17 is separated on one side from the side surface of the base layer 15 on the first buried layer 13 side, and overlaps on the other side with the upper portion of the third semiconductor layer 16. The undersurface of the source layer 17 is located in a third depth X3 (hereinafter simply referred to as the depth X3) which is shallower than the depth X1 from the surface of the second semiconductor layer 12.

On the base layer 15, and on the second semiconductor layer 12 above the first buried layer 13, a gate electrode 19 is formed with a gate insulating film 18 being interposed therebetween.

On the undersurface of the first semiconductor layer 11 (the surface thereof on the opposite side from the second semiconductor layer 12), a drain electrode (not shown) is formed. The gate electrode 19 is covered with an insulating layer (not shown) around its circumference. The source layer 17 and the third semiconductor layer 16 are connected to a source electrode (not shown).

The semiconductor device 10 in the above-described structure is configured to be able to reduce the on-resistance, while maintaining the source-drain withstand voltage.

Next, the operation of the semiconductor device 10 is described in contrast with a semiconductor device of a first comparative example, and a semiconductor device of a second comparative example.

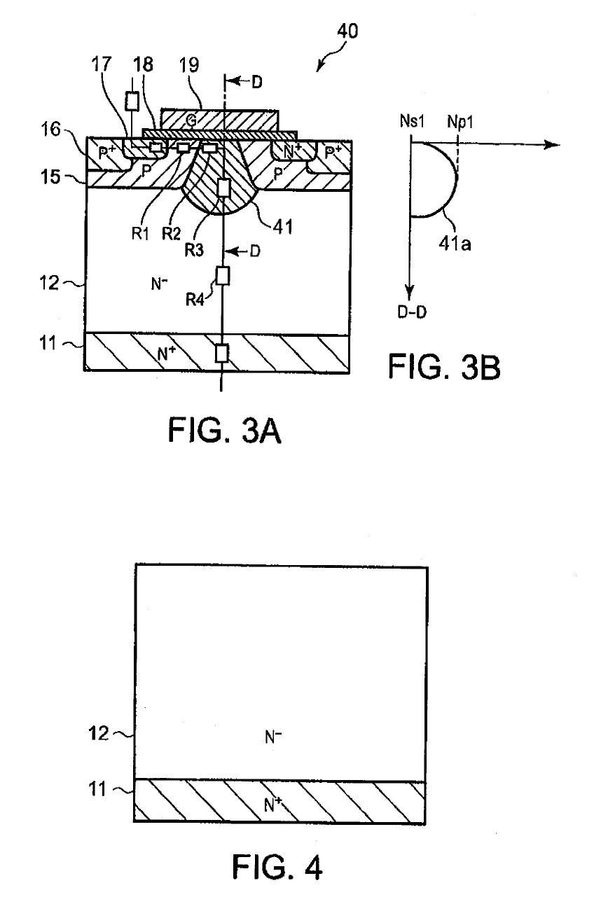

FIG. 2 shows a semiconductor device of the first comparative example; FIG. 2A shows a cross-sectional view of the semiconductor device; FIG. 2A shows the impurity concentration distribution along the line C-C in FIG. 2A. FIG. 3 shows a semiconductor device of the second comparative example; FIG. 3A shows a cross-sectional view of the semiconductor device; FIG. 3B shows the impurity concentration distribution along the line D-D in FIG. 3A.

Here, the semiconductor device of the first comparative example is a planar gate DMOS transistor which has no first buried layer 13 and no second buried layer 14. The semiconductor device of the second comparative example is a planar gate DMOS transistor which has the first buried layer 13, but has no second buried layer 14.

In a planar gate DMOS transistor, the on-resistance is determined by the total resistances on a path along which carriers move from the source layer 17 to the first semiconductor layer 11. The main elements for resistances include the channel resistance R1 of the MOS transistor, an accumulated resistance R2 in a state where carriers are accumulated in the semiconductor layer under the gate electrode 19, JFET (Junction field Effect Transistor) resistance R3 which shows tendency of the diffusion of the current from the base layer 15 under the gate electrode 19 to the second semiconductor layer 12, and a drift resistance R4 which is a bulk resistance of the second semiconductor layer 12.

The source-drain withstand voltage of the DMOS transistor is determined by the avalanche voltage of the PN junction diode formed by the base layer 15 and the second semiconductor layer 12.

As shown in FIG. 2B, in a semiconductor device 30 of the first comparative example, an impurity concentration distribution 31a of the semiconductor layer under the gate electrode 19 decreases from the surface to the inside, and has a constant value in the vicinity of the undersurface of the base layer 15. Accordingly, the impurity concentration of the semiconductor layer directly under the gate electrode 19 is high, while the impurity concentration in the vicinity of the undersurface of the base layer 15 is low.

The JFET resistance R3 depends on the impurity concentration in the area forming a JFET structure, surrounded by the lower both ends of the base layer 15. As a result, when the impurity concentration directly under the gate electrode 19 is high, and the impurity concentration in the vicinity of the undersurface of the base layer 15 is low, the JFET resistance R3 increases. Consequently, low on-resistance cannot be obtained in the semiconductor device 30 of the first comparative example.

As shown in FIG. 3, in the semiconductor device 40 of the second comparative example, the impurity concentration distribution 41a of the semiconductor layer directly under the gate electrode 19 is such that the impurity concentration of the semiconductor layer directly under the gate electrode 19 is made low, and the impurity concentration in the vicinity of the undersurface of the base layer 15 is made high by the same buried layer 41 as the first buried layer 13.

As a result, the impurity concentration in the area forming a JFET structure, surrounded by the lower both ends of the base layer 15 increases, thus the JFET resistance R3 decreases. However, as a side effect, avalanche breakdown occurs at the bottom surface end of the base layer 15, thus the source-drain withstand voltage is reduced. Consequently, low on-resistance cannot be obtained while the source-drain withstand voltage is maintained in the semiconductor device 40 of the second comparative example.

On the other hand, in the semiconductor device 10 of the present embodiment, the impurity concentration of the semiconductor layer directly under the gate electrode 19 is made high and the impurity concentration in the vicinity of the undersurface of the base layer 15 is made low by the first buried layer 13, thus the JFET resistance R3 decreases.

Furthermore, because a depletion layer can be easily extended as the charges in the first buried layer 13 are compensated by the second buried layer 14, avalanche breakdown at the bottom surface end of the base layer 15 is prevented, thus the source-drain withstand voltage is maintained. This is because the amount of the impurity in the first buried layer 13 and that in the second buried layer 14 are set to equal to each other.

Consequently, in the semiconductor device 10 of the present embodiment, low on-resistance can be obtained, while the source-drain withstand voltage is maintained.

Furthermore, because the impurity concentration directly under the gate electrode 19 is decreased, the gate charge amount at the time of switching is reduced, thus the semiconductor device 10 can be operated at a high speed.

Next, the method of manufacturing the semiconductor device 10 is described. FIGS. 4 to 8 are cross-sectional views sequentially showing the manufacturing process of the semiconductor device 10.

First, as shown in FIG. 4, on an N⁺-type silicon substrate as the first semiconductor layer 11, for example, to which approximately 1E19 cm⁻³ of arsenic (As) has been added, an N-type silicon layer as the second semiconductor layer 12 is formed where approximately 1E15 cm⁻³ of phosphorus (P) has been added to the N-type silicon layer, for example, by the vapor phase epitaxial method.

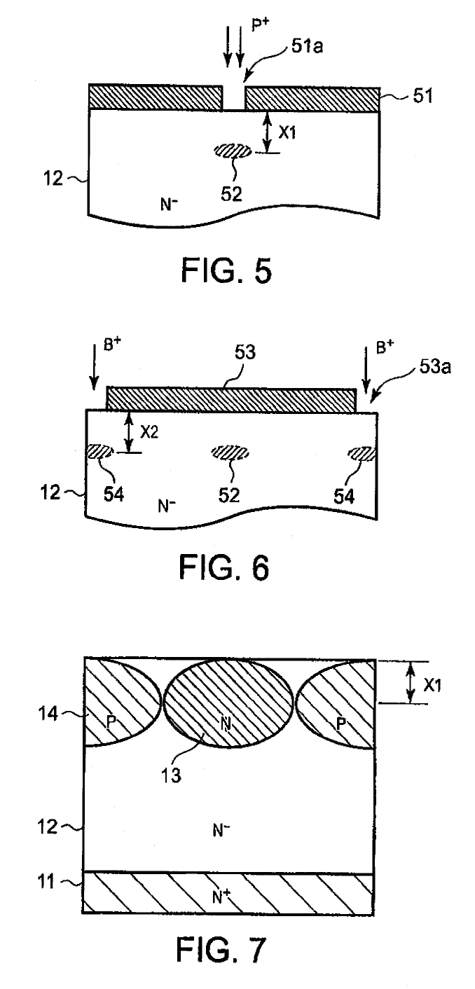

Next, as shown in FIG. 5, a resist film 51 with an opening 51a is formed on the second semiconductor layer 12, the opening 51a corresponding to the area in which the first buried layer 13 is to be formed. Approximately 2E12 cm⁻² dose of P ions (a first impurity ion) is deeply implanted into the second semiconductor layer 12 using the resist film 51 as a mask, so that an ion implantation layer 52 (a first ion implantation layer) is formed. The implantation depth of the ion implantation layer 52 is made to be the depth X1 from the surface.

Next, after the resist film 51 is removed, a resist film 53 having an opening 53a is formed as shown in FIG. 6 such that the opening 53a corresponds to the area in which the second buried layer 14 is to be formed. Approximately 2E12 cm⁻² dose of Boron (B) ions (a second impurity ion) is deeply implanted into the second semiconductor layer 12 using the resist film 53 as a mask, so that an ion implantation layer 54 (a second ion implantation layer) is formed. The implantation depth of the ion implantation layer 54 is made to be the depth X2 from the surface.

Next, after the resist film 53 is removed, activation anneal is applied as shown in FIG. 7; the first buried layer 13 is formed by thermal diffusion of P ions from the ion implantation layer 52; then the second buried layer 14 is formed by thermal diffusion of B ions from the ion implantation layer 54.

The P and B ions are diffused within the second semiconductor layer 12 isotropically. By controlling the dose to be used, the ion implantation depths, and an anneal time, the first buried layer 13 and the second buried layer 14 can be obtained in such a manner that the two layers alternately adjoin, and the upper surfaces thereof reach the surface of the second semiconductor layer 12.

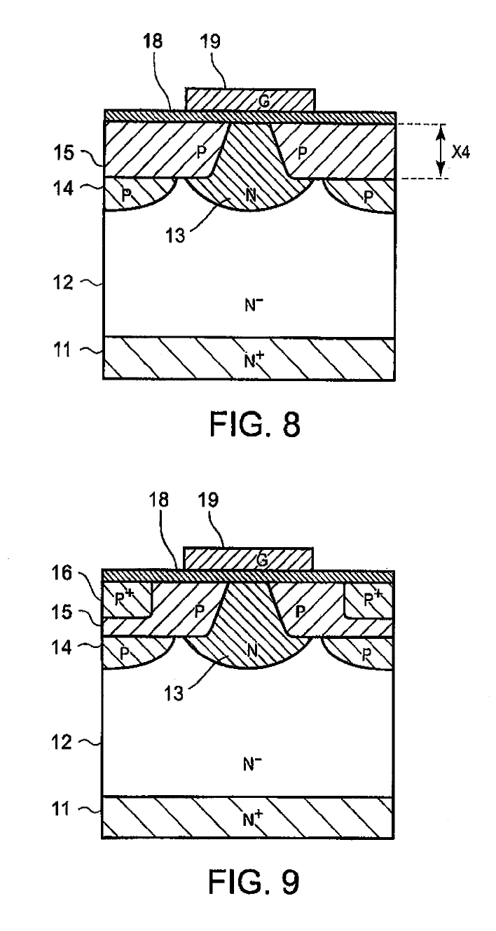

Next, as shown in FIG. 8, after the gate electrode 19 is first formed on the first buried layer 13 with the gate insulating film 18 being interposed therebetween, the P-type base layer 15 is selectively formed, that overlaps with the upper portion of the second buried layer 14, as well as the upper portion of a part of the first buried layer 13 on the second buried layer 14 side, and the undersurface of the P-type base layer 15 is located at the depth X4 which is approximately equal to the depth X1 from the surface of the second semiconductor layer 12.

Specifically, the gate insulating film 18 is formed by thermally oxidizing the surface of the second semiconductor layer 12. Next, P-added polysilicon film is formed on the gate insulating film 18 by the CVD (Chemical Vapor Deposition) method, and the gate electrode 19 is formed by patterning using the photolithography method. Next, B ions are shallowly implanted through the gate insulating film 18 by a self-aligned method using the gate electrode 19 as a mask, so that an ion implantation layer is formed on the surface of the second semiconductor layer 12.

Next, activation anneal is applied. The implanted B ions are diffused into the lower and transverse directions of the first semiconductor layer 12, and overlaps with the first buried layer 13 and the second buried layer 14, while being extended below the gate electrode 19. At this point, activation anneal conditions are adjusted so that the depth X4 of the undersurface of the base layer 15 approximately matches the depth X1.

Next, as shown in FIG. 9, the P⁺-type third semiconductor layer 16 is selectively formed in the center of the base layer 15.

Specifically, a resist film (not shown) is formed as the mask material having an opening corresponding to the area in which the third semiconductor layer 16 is formed Next, B ions are shallowly implanted through the gate insulating film 18 using the resist film as a mask, so that an ion implantation layer is formed on the surface in the center of the base layer 15. Next, after the resist film is removed, activation anneal is applied.

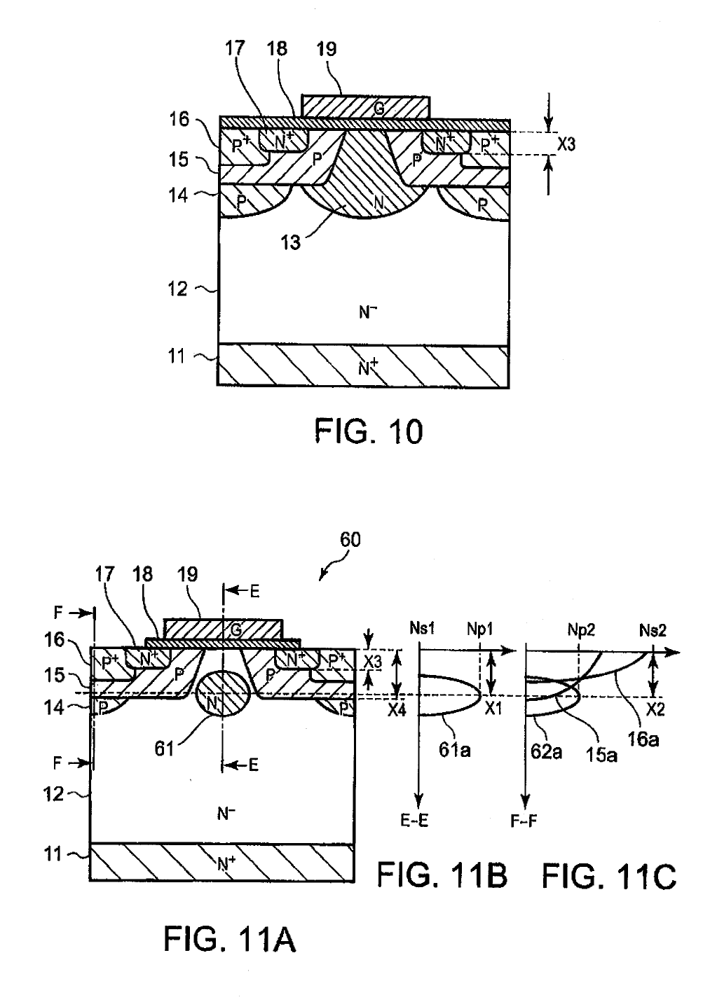

Next, as shown in FIG. 10, in the base layer 15, N⁺-type source layer 17 is selectively formed such that the source layer 17 is separated on one side from the side surface of the base layer 15 on the first buried layer 13 side, and overlaps on the other side with the upper portion of the third semiconductor layer 16, and the undersurface of the source layer 17 is located at the depth X3 shallower than the depth X1 from the surface of the second semiconductor layer 12.

Specifically, a resist film (not shown) is formed as the mask material having an opening corresponding to the area in which the source layer 17 is formed. Next, P ions are shallowly implanted through the gate insulating film 18 by a self-aligned method using the gate electrode 19 as a mask on one side and using the resist film as a mask on the other side, so that an ion implantation layer is formed on the surface of the base layer 15. Next, activation anneal is applied. The implanted P ions are diffused into the lower and transverse directions of the first semiconductor layer 12, and are separated on one side from the side surface of the base layer 15 on the first buried layer 13 side, and overlaps on the other side with the upper portion of the third semiconductor layer 16 while being extended below the gate electrode 19.

At this point, activation anneal conditions are adjusted so that the depth X3 of the undersurface of the source layer 17 is shallower than the depth X1.

Next, excessive gate insulating film 18 is removed to expose a portion of the third semiconductor layer 16 and the source layer 17. Thereby, the semiconductor device 10 shown in FIG. 1 is obtained.

As described above, in the present embodiment, the N-type first buried layer 13 having the peak impurity concentration Np1 at the depth X1 from the surface of the second semiconductor layer 12, and the P-type second buried layer 14 adjacent to the first buried layer 13, having the peak impurity concentration Np2 at the depth X2 from the surface are selectively formed.

As a result, the impurity concentration in the vicinity of the undersurface of the base layer 15 is made higher than that of the semiconductor layer directly under the gate electrode 19 by the first buried layer 13, thus the JFET resistance R3 is reduced. The charges in the first buried layer 13 are compensated by the second buried layer 14, and a depletion layer can be easily extended, thus avalanche breakdown at the bottom surface end of the base layer 15 is prevented, and the source-drain withstand voltage is maintained. Consequently, a semiconductor device having a low on-resistance and a method of manufacturing the semiconductor device are obtained.

Furthermore, because the impurity concentration directly under the gate electrode 19 is decreased, the gate charge amount at the time of switching is reduced, thus the semiconductor device can be operated at a high speed.

Although the case has been described herein where the first conductivity type is N-type and the second conductivity type is P-type, the first conductivity type may be P-type and the second conductivity type may be N-type. In this case, a P-channel DMOS transistor in which a channel is formed when a negative bias is applied to the gate is obtained.

Although the case has been described where the depth X1 of the peak impurity concentration Np1 is approximately the same as the depth X4 of the undersurface of the base layer, the two depths may be different. In that case, the depth X1 is preferably set deeper than the depth X4 from the viewpoint of achieving high-speed operation of the device.

Also, the term “adjoin” used herein includes not only the case where the boundary of the first buried layer 13 is in contact with the boundary of the second buried layer 14, but also the case where the first buried layer 13 and the second buried layer 14 partially overlap.

### Embodiment 2

A semiconductor device according to Embodiment 2 of the present invention is described using FIG. 11. FIG. 11 shows the semiconductor device according; FIG. 11A is a cross-sectional view of the semiconductor device; FIG. 11B shows impurity concentration distribution along the line E-E in FIG. 11A; FIG. 11C shows impurity concentration distribution along the line F-F in FIG. 11A.

In the present embodiment, the same components as in the above-described Embodiment 1 are labeled with the same reference symbols and the description for the same components are omitted, thus only different components are described. The present embodiment is different from Embodiment 1 in that the sizes of the first buried layer and the second buried layer are reduced.

That is to say, as shown in FIG. 11A, in the semiconductor device 60 of the present embodiment, a first buried layer 61 and a second buried layer 62 whose sizes (thickness, width) are smaller than the first buried layer 13 and the second buried layer 14 shown in FIG. 1 are formed.

Accordingly, the upper surface of the first buried layer 61 and the upper surface of the second buried layer 62 do not reach the surface of the second semiconductor layer 12, but are separated from the surface. The first buried layer 61 and the second buried layer 62 are adjacent to each other, but do not adjoin, thus are separated from each other. The base layer 15 overlaps with the upper portion of the second buried layer 62, but does not overlap with the first buried layer 61, and is separated therefrom.

As shown in FIG. 11B, an impurity concentration distribution 61a of the first buried layer 61 along the line E-E shows the peak impurity concentration Np1 at the depth X1, and forms a convex curve decreasing in the upward and downward directions of the semiconductor layer 12.

As shown in FIG. 11C, an impurity concentration distribution 62a of the second buried layer 62 along the line F-F shows the peak impurity concentration Np2 at the depth X2, and forms a convex curve decreasing in the upward and downward directions of the semiconductor layer 12.

Similarly to Embodiment 1, the peak impurity concentration Np1 and the peak impurity concentration Np2 are arranged to be approximately the same, and also the amount of the impurity of the first buried layer 61, and the amount of the impurity of the second buried layer 62 are arranged to be approximately the same.

Accordingly, even when the sizes of the first buried layer 61 and the second buried layer 62 are reduced, charge balance between the high impurity concentration in the areas forming a JFET structure, the first buried layer 61, and the second buried layer 62 is maintained.

As a result, similar effects as those of the semiconductor device 10 shown in FIG. 1, i.e., reduction of the on-resistance with the withstand voltage maintained can be achieved.

The method of manufacturing the semiconductor device 60 is basically the same as shown in FIGS. 4 to 10. The different point is that the sizes of the first buried layer 61 and the second buried layer 62 are controlled by adjusting, for example, activation anneal conditions (temperature, time). Productivity can be improved by reducing e.g., activation anneal temperature and time.

As described above, in the present embodiment, the sizes of the first buried layer 61 and the second buried layer 62 are reduced. The present embodiment has advantages in that the on-resistance can be reduced with the withstand voltage maintained, while the productivity can be improved.

### Embodiment 3

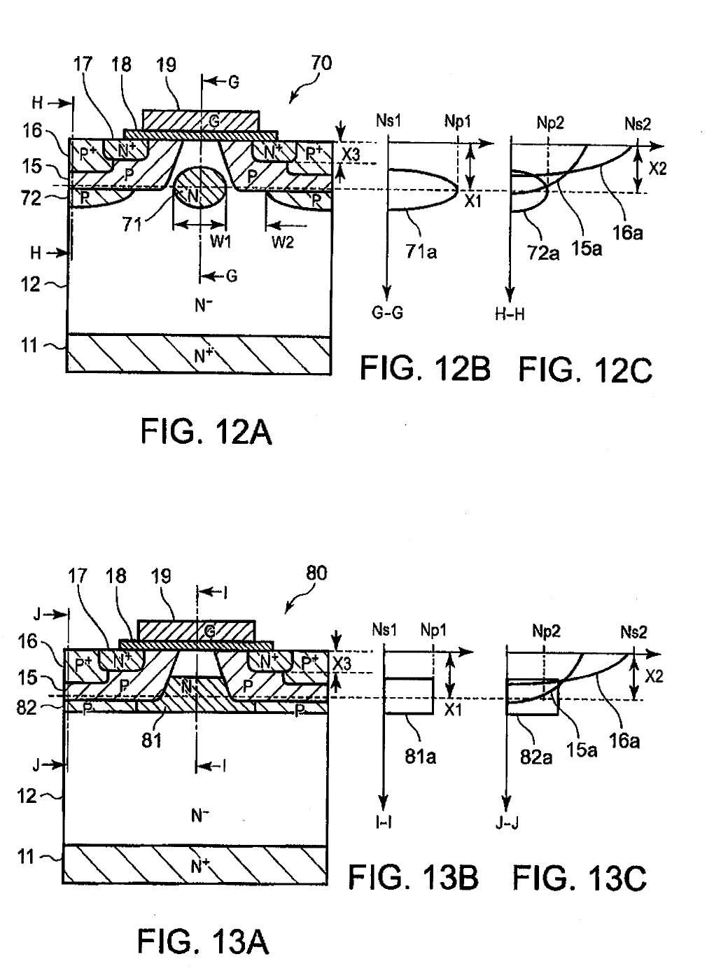

A semiconductor device according to Embodiment 3 of the present invention is described using FIG. 12. FIG. 12 shows the semiconductor device; FIG. 12A is a cross-sectional view of the semiconductor device; FIG. 12B shows impurity concentration distribution along the line G-G in FIG. 12A; FIG. 12C shows impurity concentration distribution along the line H-H in FIG. 12A.

In the present embodiment, the same components as in the above-described Embodiment 1 are labeled with the same reference symbols and the description for the same components are omitted, thus only different components are described. The point of difference between the present embodiment and Embodiment 1 is that the width of the first buried layer is made different from that of the second buried layer.

That is to say, as shown in FIG. 12A, in the semiconductor device 70 of the present embodiment, a first buried layer 71, and a second buried layer 72 which is wider than the first buried layer 71 are formed. The width W2 of the second buried layer 72 is, for example, 3 times greater than the width W1 of the first buried layer 71, and the thicknesses of the first buried layer 71 and the second buried layer 72 are set equal to each other.

The upper surface of the first buried layer 71 and the upper surface of the second buried layer 72 do not reach the surface of the second semiconductor layer 12, but are separated from the surface. The first buried layer 71 and the second buried layer 72 are adjacent to each other, but do not adjoin, thus are separated from each other. The base layer 15 overlaps with the upper portion of the second buried layer 72, but does not overlap with the first buried layer 71, and is separated therefrom.

As shown in FIG. 12B, an impurity concentration distribution 71a of the first buried layer 71 along the line G-G shows the peak impurity concentration Np1 at the depth X1, and forms a convex curve decreasing in the upward and downward directions of the semiconductor layer 12.

As shown in FIG. 12C, an impurity concentration distribution 72a of the second buried layer 72 along the line H-H shows the peak impurity concentration Np2 at the depth X2, and forms a convex curve decreasing in the upward and downward directions of the semiconductor layer 12.

Because the width W1 of the first buried layer 71 is smaller than the width W2 of the second buried layer 72, the amount of the impurity of the first buried layer 71, and the amount of the impurity of the second buried layer 72 are arranged to be approximately the same by setting the peak impurity concentration Np1, for example, 3 times greater than the peak impurity concentration Np2.

Accordingly, even when the width W1 of the first buried layer 71 and the width W2 of the second buried layer 72 are different, charge balance between the high impurity concentration in the areas forming a JFET structure, the first buried layer 71, and the second buried layer 72 is maintained.

As a result, similar effects as those of the semiconductor device 10 shown in FIG. 1, i.e., reduction of the on-resistance with the withstand voltage maintained can be achieved.

The method of manufacturing the semiconductor device 70 is basically the same as shown in FIGS. 4 to 10. The different point is that the width of the opening 53a shown in FIG. 6 is made greater than the width of the opening 51a shown in FIG. 5.

As described above, in the present embodiment, the width W2 of the second buried layer 72 is made greater than the width W1 of the first buried layer 71, and accordingly, the peak impurity concentration Np1 is made greater than the peak impurity concentration Np2. The present embodiment enables the on-resistance to be reduced with the withstand voltage maintained, while providing a suitable structure for the case where multiple DMOS transistors which are formed at predetermined intervals in the transverse direction have a large arrangement pitch between the transistors.

### Embodiment 4

A semiconductor device according to Embodiment 4 of the present invention is described using FIG. 13. FIG. 13 shows the semiconductor device; FIG. 13A is a cross-sectional view of the semiconductor device; FIG. 13B shows impurity concentration distribution along the line I-I in FIG. 13A; FIG. 13C shows impurity concentration distribution along the line J-J in FIG. 13A.

In the present embodiment, the same components as in the above-described Embodiment 1 are labeled with the same reference symbols and the description for the same components are omitted, thus only different components are described. The point of difference between the present embodiment and Embodiment 1 is that the cross sections of the first buried layer and the second buried layer are made rectangular.

That is to say, as shown in FIG. 13A, a first buried layer and a second buried layer 82 having rectangular cross-sections are formed in the semiconductor device 80 of the present embodiment.

The upper surface of the first buried layer 81 and the upper surface of the second buried layer 82 do not reach the surface of the second semiconductor layer 12, but are separated from the surface. The first buried layer 81 and the second buried layer 82 adjoin with the entire side surface. The base layer 15 overlaps with the upper portion of the second buried layer 82, and the upper portion of a part of the first buried layer 81 on the second buried layer 82 side.

As shown in FIG. 13B, an impurity concentration distribution 81a of the first buried layer 81 along the line I-I shows a rectangular shape having the depth X1 as the center, and a constant impurity concentration Np1 along the upward and downward directions of the second semiconductor layer 12.

Similarly, as shown in FIG. 13C, the impurity concentration distribution 82a of the second buried layer 82 along the line J-J shows a rectangular shape having the depth X2 as the center, and a constant impurity concentration Np2 along the upward and downward directions of the second semiconductor layer 12.

Similarly to Embodiment 1, the impurity concentration Np1 and the impurity concentration Np2 are arranged to be approximately the same, and also the amount of the impurity of the first buried layer 81, and the amount of the impurity of the second buried layer 82 are arranged to be approximately the same.

Accordingly, even when the cross-sections of the first buried layer 81 and the second buried layer 82 are rectangular shape, charge balance between the high impurity concentration in the areas forming a JFET structure, the first buried layer 81, and the second buried layer 82 is maintained.

As a result, similar effects as those of the semiconductor device 10 shown in FIG. 1, i.e., reduction of the on-resistance with the withstand voltage maintained can be achieved.

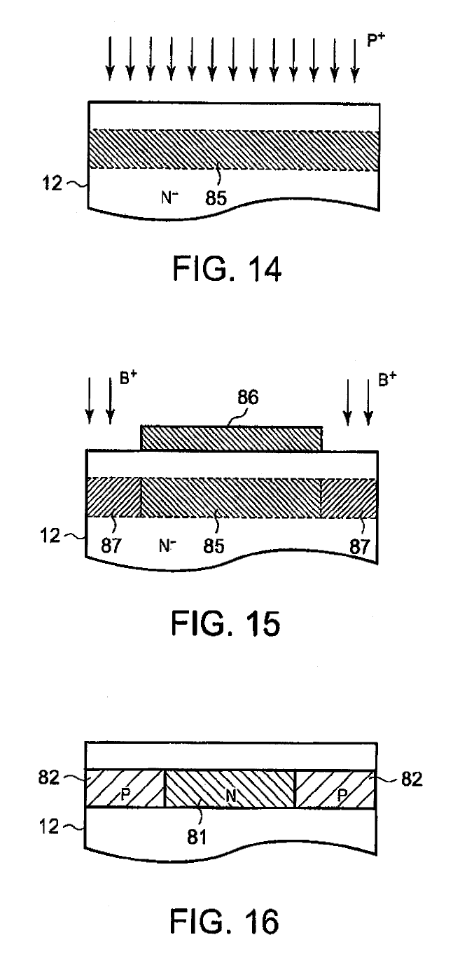

Next, the method of manufacturing the semiconductor device 80 is described. FIGS. 14 to 16 are cross-sectional views sequentially showing an essential part of the manufacturing process of the semiconductor device 80.

As shown in FIG. 14, P ions are implanted onto the entire surface of the second semiconductor layer 12, so that an ion implantation layer 85 is formed inside the second semiconductor layer 12. The ion implantation layer 85 is formed by, for example, implanting a predetermined dose of P ions, while continuously changing the acceleration energy for P ions.

Next, as shown in FIG. 15, a resist film is formed as the mask material 86 for covering the area in which the first buried layer 81 is to be formed. B ions are implanted using this resist film as a mask, so that an ion implantation layer 87 adjoining the ion implantation layer 85 is formed inside the second semiconductor layer 12. An ion implantation layer 87 is formed similarly to the ion implantation layer 85, thus description is omitted. Because P ions and B ions are implanted in a region where the ion implantation layer 87 is formed, the dose of B ions is made approximately twice as much as the dose of P ions.

However, in the case where the widths of the ion implantation layer 85 and the ion implantation layer 87 are different, the net dose for the ion implantation layer having a narrower width is increased so that the amounts of the impurity for both layers become the same.

Next, as shown in FIG. 16, activation anneal is performed to activate P ions in the implantation layer 85, and P, B ions in the implantation layer 87. In the ion implantation layer 87, the difference between B-concentration and P-concentration is the net impurity concentration.

The activation anneal, which activates the impurities ion-implanted, needs to be performed in conditions under which thermal diffusion is negligible.

Accordingly, the first buried layer 81 and the second buried layer 82 are formed such that the impurity concentration Np1 and Np2 are approximately the same, the both amounts of the impurity are approximately the same, and both layers adjoin with the entire side surface.

As described above, in the present embodiment, the cross sections of the first buried layer 81 and the second buried layer 82 are made rectangular. The present embodiment enables the on-resistance to be reduced with the withstand voltage maintained, while the P and B ions do not need to be thermally diffused deeper into the semiconductor layer, which is advantageous for simplifying the manufacturing process.

Although the case has been described where the first buried layer 81 and the second buried layer 82 are formed by the ion implantation method, both layers may be formed by an epitaxial method.

Specifically, a p-doped silicon layer is epitaxially grown on an N-type silicon layer. Next, on the area to be formed into the first buried layer 81, silicon oxide is formed as a mask material by, for example, a thermal oxidation method. Next, each silicon layer which has been P-doped using the silicon oxide as a mask is selectively removed, so that the first buried layer 81 is formed.

Next, B-doped silicon layer is epitaxially grown on an N-type silicon layer by a selective growth method, so that the second buried layer 82 is formed. Next, after the mask material is removed, an N-type silicon layer is epitaxially grown on the P-doped silicon layer, and the B-doped silicon layer. The N-type silicon layer on the both sides of the first buried layer 81 and the second buried layer 82 serves as the second semiconductor layer 12.

### Embodiment 5

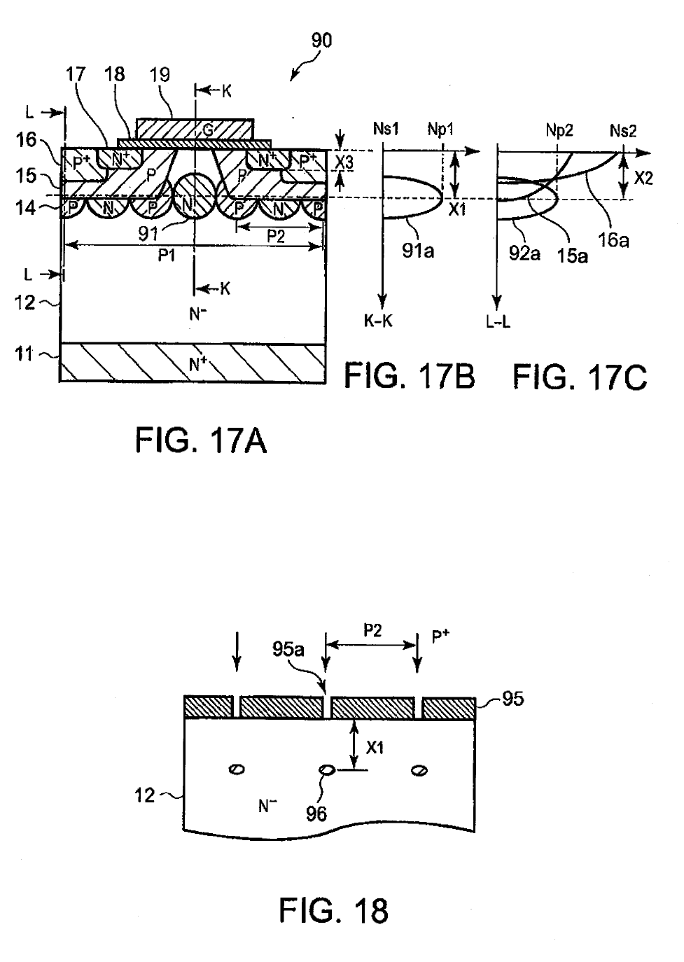

A semiconductor device according to Embodiment 5 of the present invention is described using FIG. 17. FIG. 17 shows a semiconductor device; FIG. 17A is a cross-sectional view of the semiconductor device; FIG. 17B shows impurity concentration distribution along the line K-K in FIG. 17A; FIG. 17C shows impurity concentration distribution along the line L-L in FIG. 17A.

In the present embodiment, the same components as in the above-described Embodiment 1 are labeled with the same reference symbols and the description for the same components are omitted, thus only different components are described. The point of difference between the present embodiment and Embodiment 1 is that the repetitive pitch of the first and second buried layers is made smaller than the repetitive pitch of DMOS transistors.

That is to say, as shown in FIG. 17A, in the semiconductor device 90 of the present embodiment, the first semiconductor layer 91 and the second semiconductor layer 92 both having a circular cross-section alternately adjoin.

The repetitive pitch P2 of the first semiconductor layer 91 and the second semiconductor layer 92 is set to a unit fraction times the repetitive pitch P1 of the MOS transistor where the unit fraction is set to ⅓.

The upper surface of the first buried layer 91 and the upper surface of the second buried layer 92 do not reach the surface of the second semiconductor layer 12, but are separated from the surface. The base layer 15 overlaps with the upper portion of the second buried layer 92, and the upper portion of the first buried layer 91 excluding the first buried layer 91, formed under the gate electrode 19.

As shown in FIG. 17B, an impurity concentration distribution 91a of the first buried layer 71 along the line K-K shows the peak impurity concentration Np1 at the depth X1, and forms a convex curve decreasing in the upward and downward directions of the semiconductor layer 12.

As shown in FIG. 17C, an impurity concentration distribution 92a of the second buried layer 92 along the line L-L shows the peak impurity concentration Np2 at the depth X2, and forms a convex curve decreasing in the upward and downward directions of the semiconductor layer 12.

Similarly to Embodiment 1, the impurity concentration Np1 and the impurity concentration Np2 are arranged to be approximately the same, and also the amount of the impurity of the first buried layer 81, and the amount of the impurity of the second buried layer 82 are arranged to be approximately the same.

Accordingly, even when the repetitive pitch P2 of the first buried layer 91 and the second buried layer 92 is made smaller than the repetitive pitch P1 of the MOS transistor, charge balance between the high impurity concentration in the areas forming a JFET structure, the first buried layer 91, and the second buried layer 92 is maintained.

As a result, similar effects as those of the semiconductor device 10 shown in FIG. 1, i.e., reduction of the on-resistance with the withstand voltage maintained can be achieved.

Next, the method of manufacturing the semiconductor device 90 is described. FIGS. 18 to 20 are cross-sectional views sequentially showing an essential part of the manufacturing process of the semiconductor device 90.

Next, as shown in FIG. 5, a resist film 95 with multiple openings 95a is formed on the second semiconductor layer 12, the openings 95a corresponding to the areas in which the first buried layer 91 is to be formed with the pitch P2. For example, approximately 2E12 cm⁻² dose of P ions is deeply implanted into the second semiconductor layer 12 using the resist film 95 as a mask, so that an ion implantation layer 96 is formed inside the second semiconductor layer 12.

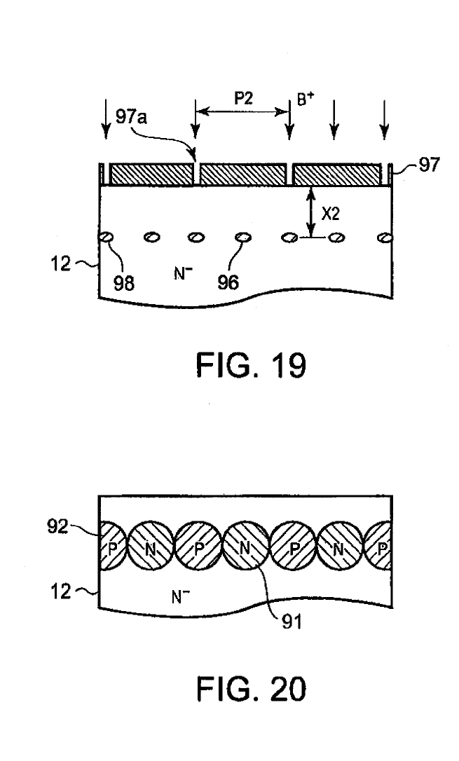

Next, after resist film 95 is removed, a resist film 97 with multiple openings 97a is formed as shown in FIG. 19, the openings 97a corresponding to the areas in which the second buried layer 92 is to be formed with the pitch P2. For example, approximately 2E12 cm⁻² dose of B ions is deeply implanted into the second semiconductor layer 12 using the resist film 97 as a mask, so that an ion implantation layer 98 is formed inside the second semiconductor layer 12.

Next, after the resist film 97 is removed, activation anneal is applied as shown in FIG. 20; the first buried layer 91 is formed by thermal diffusion of P ions from the ion implantation layer 96; then the second buried layer 92 is formed by thermal diffusion of B ions from the ion implantation layer 92.

As described above, in the present embodiment, the repetitive pitch P2 of the first buried layer 91 and the second buried layer 92 is made smaller than the repetitive pitch P1 of the MOS transistor, however, charge balance between the first buried layer 91 and the second buried layer 92 is maintained. The present embodiment provides a suitable structure for the case where DMOS transistors having different pitches are formed in the same wafer.

### Embodiment 6

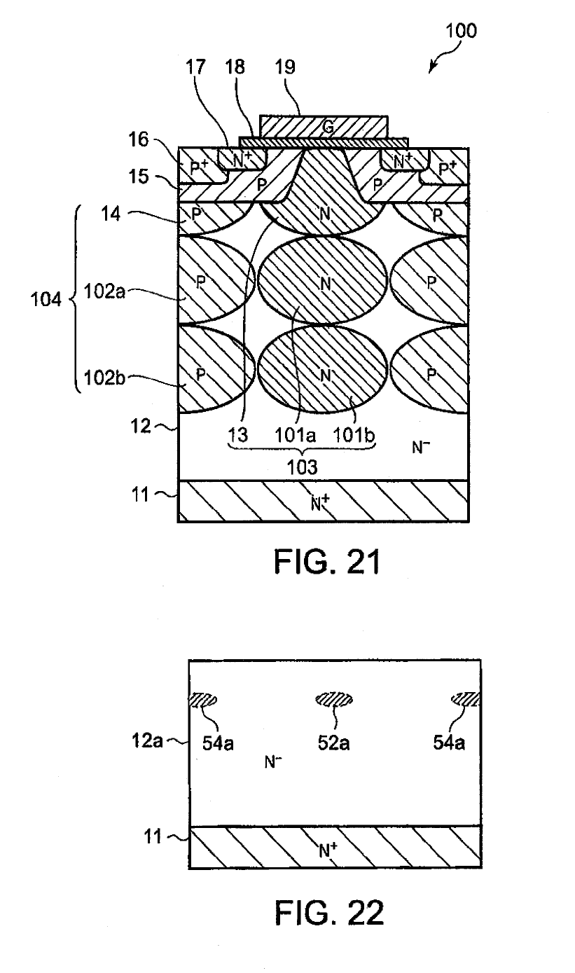

A semiconductor device according to Embodiment 6 of the present invention is described using FIG. 21. FIG. 21 is a cross-sectional view showing the semiconductor device. In the present embodiment, the same components as in the above-described Embodiment 1 are labeled with the same reference symbols and the description for the same components are omitted, thus only different components are described. The point of difference between the present embodiment and Embodiment 1 is that below the first buried layer and the second buried layer, multiple buried layers having the same conductivity type as the layer above are formed, respectively.

That is to say, as shown in FIG. 21, in the semiconductor device 100 of the present embodiment, an N-type third buried layer 101a is formed to adjoin the undersurface of the first buried layer 13. An N-type fifth buried layer 101b is formed to adjoin the undersurface of the third buried layer 101a.

Similarly, a P-type fourth buried layer 102a is formed to adjoin the undersurface of the second buried layer 14. A P-type sixth buried layer 102b is formed to adjoin the undersurface of the fourth buried layer 102a.

Furthermore, the lateral portion of the third buried layer 101a and the lateral portion of the fourth buried layer 102a adjoin; the lateral portion of the fifth buried layer 101b, and the lateral portion of the sixth buried layer 102b adjoin.

The first buried layer 13, the third buried layer 101a, and the fifth buried layer 101b which adjoin in the depth direction constitute an N-type pillar layer 103, while the second buried layer 14, the fourth buried layer 102a, and the sixth buried layer 102b which adjoin in the depth direction constitute a P-type pillar layer 104. The semiconductor device 100 is so-called DMOS transistor in the super junction structure.

Thereby, in addition to the reduction of JFET resistance R3 with the withstand voltage maintained, the drift resistance R4 can be reduced by the N-type pillar layer 103.

Next, the method of manufacturing the semiconductor device 100 is described. FIGS. 22 to 24 are cross-sectional views sequentially showing an essential part of the manufacturing process of the semiconductor device 100.

Next, as shown in FIG. 22, an epitaxial layer 12a which is to be a part of the second semiconductor layer 12 is grown on the first semiconductor layer 11 by the epitaxial method similarly to FIG. 4. Next, similarly to FIGS. 5 and 6, an ion implantation layer 52a and an ion implantation layer 54a are formed inside the epitaxial layer 12a.

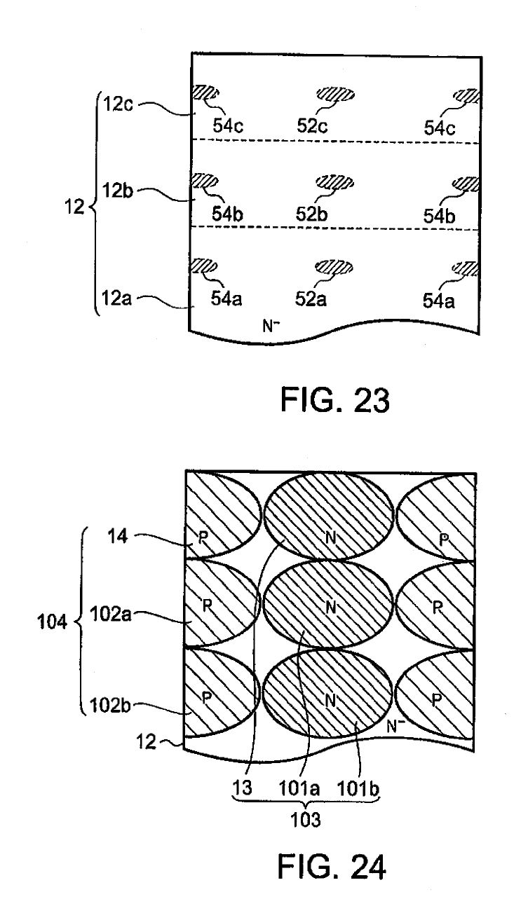

Next, as shown in FIG. 23, by repeating the process shown in FIG. 22 twice, multiple epitaxial layers 12a, 12b, and 12c are stacked, so that the second semiconductor layer 12 is formed with multiple ion implantation layers 52a, 52b, and 52c and multiple ion implantation layers 54a, 54b, and 54c being arranged in the width direction.

Specifically, the epitaxial layer 12b which is to be a part of the second semiconductor layer 12 is grown on the epitaxial layer 12a. The ion implantation layer 52b and the ion implantation layer 54b are formed inside the epitaxial layer 12b. The epitaxial layer 12c which is to be a part of the second semiconductor layer 12 is grown on the epitaxial layer 12b. The ion implantation layer 52c and the ion implantation layer 54c are formed inside the epitaxial layer 12c.

Next, as shown in FIG. 24, activation anneal is applied, P ions are thermally diffused from the ion implantation layers 52a, 52b, and 52c, and B ions are thermally diffused from the ion implantation layers 54a, 54b, and 54c. Thereby, the N-type third buried layer 101a and the N-type fifth buried layer 101b are formed in such a manner as to adjoin in the depth direction under the undersurface of the first buried layer 13 inside the second semiconductor layer 12. The P-type fourth buried layer 102a and the P-type sixth buried layer 102b are formed in such a manner as to adjoin in the depth direction under the undersurface of the second buried layer 14 inside the second semiconductor layer 12.

As a result, N-type pillar layer 103 is formed with the first buried layer 13, the thirdburied layer 101a, and the fifth buried layer 101b. P-type pillar layer 104 is formed with the second buried layer 14, the fourth buried layer 102a, and the sixth buried layer 102b.

As described above, in the present embodiment, the DMOS transistor in the super junction structure is formed such that the first buried layer 13, the third buried layer 101a, and the fifth buried layer 101b constitute the N-type pillar layer 103, and the second buried layer 14, the fourth buried layer 102a, and the sixth buried layer 102b constitute the P-type pillar layer 104.

Consequently, in addition to the reduction of JFET resistance R3 with the withstand voltage maintained, the drift resistance R4 can be reduced by the N-type pillar layer 103.

The case has been described where two buried layers are formed under each of the first buried layer 13 and the second buried layer 14, however, the number of the buried layers to be formed is not specifically limited.

In the above-described embodiments, the case has been described where the cross sections of the N-type first buried layer and the P-type second buried layer include the same amount of impurity, and charge balance between the first buried layer and the second buried layer is maintained, however, the present invention is not limited to this case.

Even though the cross sections of the N-type first buried layer and the P-type second buried layer do not include the same amount of impurity, when the amount of impurity per unit volume are the same for both layers due to the balance of the amounts of impurity included in cross-sections, similar effects can be obtained. The point is that the first buried layer and the second buried layer include the same amount of impurity per unit volume, which provides a structure to enable the JFET resistance R3 to be reduced with the withstand voltage maintained.

Consequently, the planar shape of the N-type first buried layer below the gate electrode may be not only a strip shape, but also other shape such as a hexagon or other polygon.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a first semiconductor layer of a first conductivity type;
a second semiconductor layer of the first conductivity type, the second semiconductor layer being formed on the first semiconductor layer and having a lower impurity concentration than the first semiconductor layer;
a first buried layer of the first conductivity type, the first buried layer being selectively formed in the second semiconductor layer and having a first peak impurity concentration at a first depth from a surface of the second semiconductor layer, the first peak impurity concentration being higher than an impurity concentration directly under the surface of the second semiconductor layer;
a second buried layer of a second conductivity type, the second buried layer being selectively formed in the second semiconductor layer and being adjacent to the first buried layer, the second buried layer having a second peak impurity concentration at a second depth from the surface of the second semiconductor layer, the second depth being approximately equal to the first depth;
a base layer of the second conductivity type, the base layer being selectively formed in the second semiconductor layer and overlapping with an upper portion of the second buried layer;
a source layer of the first conductivity type, the source layer being selectively formed in the base layer and being separated from a side surface of the base layer on the first buried layer side, the source layer having an undersurface located at a third depth, from the surface of the second semiconductor layer, the third depth being shallower than the first depth; and
agate electrode formed on the base layer and on the second semiconductor layer above the first buried layer with a gate insulating film being interposed therebetween.

2. The semiconductor device according to claim 1, wherein a fourth depth from the surface of the second semiconductor layer to the undersurface of the base layer is approximately equal to the first depth.

3. The semiconductor device according to claim 1, further comprising:
a plurality of third buried layers of the first conductivity types, the third buried layers being formed in such a manner as to adjoin in a depth direction under the undersurface of the first buried layer in the second semiconductor layer; and
a plurality of fourth buried layers of the second conductivity types, that are formed in such a manner as to adjoin in the depth direction under the undersurface of the second buried layer in the second semiconductor layer.

4. The semiconductor device according to claim 1, wherein
an upper surface of the first buried layer and an upper surface of the second buried layer reach the surface of the second semiconductor layer,
the first buried layer and the second buried layer adjoin, and
the base layer overlaps with the upper portion of the first buried layer on the second buried layer side.

5. The semiconductor device according to claim 1, wherein
the upper surface of the first buried layer and the upper surface of the second buried layer are separated from the surface of the second semiconductor layer, and
the first buried layer and the second buried layer are separated.

6. The semiconductor device according to claim 1, wherein
the second buried layer has a width greater than that of the first buried layer, and
the first peak impurity concentration is greater than the second peak impurity concentration.

7. The semiconductor device according to claim 1, wherein
the upper surface of the first buried layer and the upper surface of the second buried layer are separated from the surface of the second semiconductor layer,
the first buried layer and the second buried layer adjoin at an entire side surfaces, and
the base layer overlaps with the upper portion of the first buried layer on the second buried layer side.

8. The semiconductor device according to claim 1, wherein
the upper surface of the first buried layer and the upper surface of the second buried layer are separated from the surface of the second semiconductor layer, and
the first buried layer and the second buried layer alternately adjoin.

9. The semiconductor device according to claim 3, wherein a side surface of the third buried layer and a side surface of the fourth buried layer adjoin.

10. The semiconductor device according to claim 1, wherein an amount of impurity of the first buried layer and an amount of impurity of the second buried layer are approximately equal.

11. A method of manufacturing a semiconductor device, comprising:
epitaxially growing a second semiconductor layer of a first conductivity type on a first semiconductor layer of the first conductivity type, the second semiconductor layer having a lower impurity concentration than the first semiconductor layer;
implanting ions of a first impurity of the first conductivity type and ions of a second impurity of a second conductivity type into the second semiconductor layer to thereby form a first ion implantation layer and a second ion implantation layer, respectively, and diffusing the first and second impurities with heat to form a first buried layer of the first conductivity type at a first depth from the surface of the second semiconductor layer in the second semiconductor layer and a second buried layer of the second conductivity type, the first buried layer having a first peak impurity concentration higher than an impurity concentration directly under the surface of the second semiconductor layer, the second buried layer being adjacent to the first buried layer and having a second peak impurity concentration at a second depth approximately equal to the first depth from the surface of the second semiconductor layer;
forming a gate electrode on the second semiconductor layer above the first buried layer with a gate insulating film being interposed therebetween;
selectively implanting ions of the second impurity into the second semiconductor layer using the gate electrode as a mask to thereby form a base layer of the second conductivity type, the base layer overlapping with the upper portion of the second buried layer; and
selectively implanting ions of the first impurity into the base layer using the gate electrode as a mask to thereby form a source layer of the first conductivity type, the source layer being separated from a side surface of the base layer on the first buried layer side, and having an undersurface located at a third depth shallower than the first depth from the surface of the second semiconductor layer.

12. The method of manufacturing a semiconductor device according to claim 11, wherein a fourth depth from the surface of the second semiconductor layer to the undersurface of the base layer is approximately equal to the first depth.

13. The method of manufacturing a semiconductor device according to claim 11, wherein
an upper surface of the first buried layer and an upper surface of the second buried layer reach the surface of the second semiconductor layer,
the first buried layer and the second buried layer adjoin, and
the base layer overlaps with the upper portion of the first buried layer on the second buried layer side.

14. The method of manufacturing a semiconductor device according to claim 11, wherein
the upper surface of the first buried layer and the upper surface of the second buried layer are separated from the surface of the second semiconductor layer, and
the first buried layer and the second buried layer are separated.

15. The method of manufacturing a semiconductor device according to claim 11, wherein
the second buried layer has a width greater than that of the first buried layer, and
the first peak impurity concentration is greater than the second peak impurity concentration.

16. The method of manufacturing a semiconductor device according to claim 11, wherein
the upper surface of the first buried layer and the upper surface of the second buried layer are separated from the surface of the second semiconductor layer,
the first buried layer and the second buried layer adjoin at an entire side surface, and
the base layer overlaps with the upper portion of the first buried layer on the second buried layer side.

17. The method of manufacturing a semiconductor device according to claim 11, wherein
the upper surface of the first buried layer and the upper surface of the second buried layer are separated from the surface of the second semiconductor layer, and
the first buried layer and the second buried layer alternately adjoin.

18. The method of manufacturing a semiconductor device according to claim 11, wherein an amount of impurity of the first buried layer and an amount of impurity of the second buried layer are approximately equal.

19. A method of manufacturing a semiconductor device comprising:
growing a first epitaxial layer on a first semiconductor layer of a first conductivity type, the first epitaxial layer being to be apart of a second semiconductor layer of the first conductivity type, the second semiconductor layer having a lower impurity concentration than the first semiconductor layer;
implanting ions of a third impurity of the first conductivity type and ions of a fourth impurity of a second conductivity type into the first epitaxial layer to thereby form a third ion implantation layer and a fourth ion implantation layer, respectively;
growing a second epitaxial layer on the first epitaxial layer, the second epitaxial layer being to be a part of the second semiconductor layer of the first conductivity type, the second semiconductor layer having the impurity concentration lower than the first semiconductor layer;
implanting ions of a first impurity of the first conductivity type and ions of a second impurity of the second conductivity type into the second epitaxial layer to thereby form a first ion implantation layer and a second ion implantation layer, respectively;
diffusing the first to fourth impurities with heat to thereby form a first buried layer of the first conductivity type at a first depth from the surface of the second semiconductor layer in the second semiconductor layer, a second buried layer of the second conductivity type, a third buried layer of the first conductivity type directly under the first buried layer, and a fourth buried layer of the second conductivity type directly under the second buried layer, the first buried layer having a first peak impurity concentration higher than an impurity concentration directly under the surface of the second semiconductor layer, the second buried layer being adjacent to the first buried layer and having a second peak impurity concentration at a second depth approximately equal to the first depth from the surface of the second semiconductor layer;
forming a gate electrode on the second semiconductor layer above the first buried layer with a gate insulating film being interposed therebetween;
selectively implanting ions of the second impurity into the second semiconductor layer using the gate electrode as a mask to thereby form a base layer of the second conductivity type, the base layer overlapping with the upper portion of the second buried layer; and
selectively implanting ions of the first impurity into the base layer using the gate electrode as a mask to thereby form a source layer of the first conductivity type, the source layer being separated from a side surface of the base layer on the first buried layer side and having an undersurface located at a third depth shallower than the first depth from the surface of the second semiconductor layer.

20. The method of manufacturing a semiconductor device according to claim 19, wherein a side surface of the third buried layer and a side surface of the fourth buried layer adjoin.
